(19) United States
(12) Patent Application Publication
(10) Pub. No.: US 2023/0266376 A1
(43) Pub. Date: Aug. 24, 2023

(54) TEST STRUCTURE AND TEST METHOD

(71) Applicant: CHANGXIN MEMORY TECHNOLOGIES, INC., Hefei City (CN)

(72) Inventor: Zhongqin ZHU, Hefei City (CN)

(73) Assignee: CHANGXIN MEMORY TECHNOLOGIES, INC., Hefei City (CN)

(21) Appl. No.: 17/894,489

(22) Filed: Aug. 24, 2022

Related U.S. Application Data
(63) Continuation of application No. PCT/CN2022/092969, filed on May 16, 2022.

(30) Foreign Application Priority Data
Feb. 24, 2022 (CN) 202210175397.2

(51) Int. Cl. G01R 31/08; G01R 31/28

(52) U.S. Cl. CPC G01R 31/08; G01R 31/2886

(57) ABSTRACT

A test structure and a test method are provided. The test structure includes: a first interdigital structure including first and second conductive comb tooth portions, where comb tooth ends of the second and first conductive comb tooth portions are arranged alternately in sequence and spaced apart and there is a first distance between the comb tooth ends of the second and first conductive comb tooth portions; and a second interdigital structure including third and fourth conductive comb tooth portions, where comb tooth ends of the fourth and third conductive comb tooth portions are arranged alternately in sequence and spaced apart; there is a second distance between the comb tooth ends of the fourth and third conductive comb tooth portions, which is not equal to the first distance; and the first and second conductive comb tooth portions are electrically connected to the third and fourth conductive comb tooth portions respectively.

### CROSS-REFERENCE TO RELATED APPLICATIONS

This is a continuation of International Patent Application No. PCT/CN2022/092969, filed on May 16, 2022, which claims priority to Chinese Patent Application No. 202210175397.2, filed on Feb. 24, 2022. The disclosures of these applications are hereby incorporated by reference in their entirety.

### BACKGROUND

A test structure (test key) is a graphic structure specially used to test chip performance. By detecting device parameters on the test structure, process fluctuations of a production line can be monitored, and early warnings of possible unexpected situations can be given.

During the research and development process, a large quantity of test structures are made to test the support capability of a new process, which will then be fed back to the design content to ensure that the size of the design meets the requirements of the new process. This includes the detection of a distance between most basic structural units (such as metal wires and the like). The conventional test method includes: providing a test structure with adjacent structural units, and measuring whether there is a short circuit between the structural units to find the suitable shortest distance. However, the conventional test structure can only detect one distance, and the test efficiency is low.

### SUMMARY

This disclosure relates to the field of integrated circuit technologies, and in particular, to a test structure and a test method.

According to various embodiments of the disclosure, a test structure and a test method are provided.

At a first aspect of the disclosure, there is provided a test structure, including a first interdigital structure and a second interdigital structure.

The first interdigital structure includes a first conductive comb tooth portion and a second conductive comb tooth portion. Comb tooth ends of the second conductive comb tooth portion are inserted into the first conductive comb tooth portion. The comb tooth ends of the second conductive comb tooth portion and comb tooth ends of the first conductive comb tooth portion are arranged alternately in sequence and spaced apart, and there is a first distance between the comb tooth end of the second conductive comb tooth portion and the comb tooth end of the first conductive comb tooth portion.

The second interdigital structure includes a third conductive comb tooth portion and a fourth conductive comb tooth portion. Comb tooth ends of the fourth conductive comb tooth portion are inserted into the third conductive comb tooth portion. The comb tooth ends of the fourth conductive comb tooth portion and comb tooth ends of the third conductive comb tooth portion are arranged alternately in sequence and spaced apart. There is a second distance between the comb tooth end of the fourth conductive comb tooth portion and the comb tooth end of the third conductive comb tooth portion. The second distance is not equal to the first distance. The first conductive comb tooth portion is electrically connected to the third conductive comb tooth portion, and the second conductive comb tooth portion is electrically connected to the fourth conductive comb tooth portion.

At a second aspect of the disclosure, there is disclosed a test method, including the following operations.

The test structure according to any one of the foregoing embodiments is provided.

A first voltage and a second voltage are applied to two opposite ends of the test structure respectively, to measure a current flowing through the test structure, where there is a voltage difference between the first voltage and the second voltage.

A position of a short circuit occurred in the test structure is determined based on the measured current and the voltage difference between the first voltage and the second voltage.

Details of one or more embodiments of the disclosure are provided in the accompanying drawings and descriptions below. Other features, objectives, and advantages of the disclosure become apparent from the specification, the accompanying drawings, and the claims.

### BRIEF DESCRIPTION OF THE DRAWINGS

In order to describe the technical solutions in the embodiments of the disclosure more clearly, the accompanying drawings required for describing the embodiments are introduced briefly below. Apparently, the accompanying drawings in the following description show only some embodiments of the disclosure, and a person of ordinary skill in the art may still derive drawings of other embodiments from these accompanying drawings without creative efforts.

FIG. 1 is a schematic structural diagram from top view of a test structure according to an embodiment of the disclosure;

FIG. 2 is a schematic structural diagram from top view of a test structure according to an embodiment of the disclosure; and

FIG. 3 is a flowchart of a test method according to an embodiment of the disclosure.

### DETAILED DESCRIPTION

For ease of understanding the disclosure, the disclosure is described below more comprehensively with reference to the related accompanying drawings. Preferred embodiments of the disclosure are shown in the accompanying drawings. However, the disclosure may be implemented in many different forms and is not limited to the embodiments described herein. On the contrary, these embodiments are provided to make the contents of the disclosure more thorough and comprehensive.

Unless otherwise defined, all technical and scientific terms used herein have the same meaning as that commonly understood by a person of ordinary skill in the art to which the disclosure belongs. The terms used herein in the specification of the disclosure are merely for the purpose of describing specific embodiments, and are not intended to limit the disclosure.

It will be understood that when an element or layer is referred to as being “on”, “connected to”, or “coupled to” another element or layer, it may be directly on, connected to, or coupled to the another element or layer, or an intermediate element or layer may exist. In contrast, when an element is referred to as being “directly on”, “directly connected to”, or “directly coupled to” another element or layer, no intermediate element or layer exists. It will be understood that, although the terms “first”, “second”, “third”, and the like may be used to describe various elements, components, regions, layers, and/or parts, these elements, components, regions, layers, and/or parts should not be limited by these terms. These terms are only used to distinguish one element, component, region, layer, or part from another element, component, region, layer, or part. Therefore, a first element, component, region, layer, or part discussed below could be represented as a second element, component, region, layer, or part without departing from the teachings of the disclosure.

The terms used herein are for the purpose of describing specific embodiments only and are not intended to be limiting of the disclosure. As used herein, the singular forms “a”, “an”, and “the” are intended to include the plural forms as well, unless the context clearly dictates otherwise. It is also to be understood that the terms “constitute” and/or “include”, when used in this specification, identify the presence of stated features, integers, steps, operations, elements, and/or components, but do not exclude the presence or addition of one or more other features, integers, steps, operations, elements, components, and/or groups. As used herein, the term “and/or” includes any and all combinations of the associated listed items.

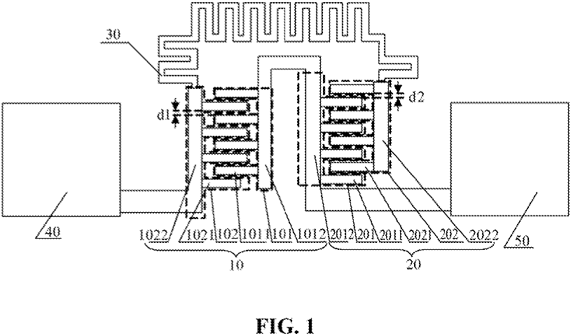

Refer to FIG. 1 to FIG. 3. It should be noted that the figures provided in the embodiments are only used to illustrate the basic concept of the disclosure in a schematic way. The figures only show the components related to the disclosure, and are not drawn according to the quantities, shapes, and sizes of the components in actual implementation. In actual implementation, the types, quantities, and proportions of the components may be changed randomly, and the component layout may also be more complicated.

Referring to FIG. 1, in an embodiment of the disclosure, a test structure is provided. The test structure includes: a first interdigital structure 10 and a second interdigital structure 20. The first interdigital structure 10 includes a first conductive comb tooth portion 101 and a second conductive comb tooth portion 102. Comb tooth ends of the second conductive comb tooth portion 102 are inserted into the first conductive comb tooth portion 101.The comb tooth ends of the second conductive comb tooth portion 102 and comb tooth ends of the first conductive comb tooth portion 101 are arranged alternately in sequence and spaced apart, and there is a first distance d1 between the comb tooth end of the second conductive comb tooth portion 102 and the comb tooth end of the first conductive comb tooth portion 101. The second interdigital structure 20 includes a third conductive comb tooth portion 201 and a fourth conductive comb tooth portion 202. Comb tooth ends of the fourth conductive comb tooth portion 202 are inserted into the third conductive comb tooth portion 201. The comb tooth ends of the fourth conductive comb tooth portion 202 and comb tooth ends of the third conductive comb tooth portion 201 are arranged alternately in sequence and spaced apart. There is a second distance d2 between the comb tooth end of the fourth conductive comb tooth portion 202 and the comb tooth end of the third conductive comb tooth portion 201. The second distance d2 is not equal to the first distance d1. The first conductive comb tooth portion 101 is electrically connected to the third conductive comb tooth portion 201, and the second conductive comb tooth portion 102 is electrically connected to the fourth conductive comb tooth portion 202.

The test structure in this embodiment of the disclosure includes a first interdigital structure 10 and a second interdigital structure 20. There is a first distance d1 between a comb tooth end of a first conductive comb tooth portion 101 and a comb tooth end of a second conductive comb tooth portion 102 of the first interdigital structure 10, and there is a second distance d2 between a comb tooth end of a third conductive comb tooth portion 201 and a comb tooth end of a fourth conductive comb tooth portion 202 of the second interdigital structure 20. The first distance d1 is not equal to the second distance d2. By means of the arrangement above, one test structure can test two different distances at the same time, which can significantly improve the test efficiency; and by using the arrangement of the interdigital structures, comb tooth ends formed by a plurality of metal wires can be detected at the same time, and the test structure in this embodiment of the disclosure is relatively compact and has a relatively small size.

In an example, the test structure further includes a voltage divider 30, electrically connecting the second conductive comb tooth portion 102 to the fourth conductive comb tooth portion 202.

Specifically, the voltage divider 30 may include, but is not limited to, a resistor.

In an example, the voltage divider 30 may be, but is not limited to, a sinuous linear resistor.

In an example, a resistance value of the first conductive comb tooth portion 101, a resistance value of the second conductive comb tooth portion 102, a resistance value of the third conductive comb tooth portion 201, and a resistance value of the fourth conductive comb tooth portion 202 are all less than a resistance value of the voltage divider 30.

Specifically, the resistance value of the first conductive comb tooth portion 101, the resistance value of the second conductive comb tooth portion 102, the resistance value of the third conductive comb tooth portion 201, and the resistance value of the fourth conductive comb tooth portion 202 are all much less than the resistance value of the voltage divider 30. More specifically, each of the resistance value of the first conductive comb tooth portion 101, the resistance value of the second conductive comb tooth portion 102, the resistance value of the third conductive comb tooth portion 201, and the resistance value of the fourth conductive comb tooth portion 202 may be, but is not limited to, less than 10% of the resistance value of the voltage divider 30, and the like, for example, 10%, 5%, or 1% of the resistance value of the voltage divider 30.

By setting the resistance value of the first conductive comb tooth portion 101, the resistance value of the second conductive comb tooth portion 102, the resistance value of the third conductive comb tooth portion 201, and the resistance value of the fourth conductive comb tooth portion 202 to be all less than the resistance value of the voltage divider 30, influence of the resistance value of the first conductive comb tooth portion 101, the resistance value of the second conductive comb tooth portion 102, the resistance value of the third conductive comb tooth portion 201, and the resistance value of the fourth conductive comb tooth portion 202 on the test result of the test structure can be reduced. In the case of the setting of the relatively large resistance value of the voltage divider 30, the test current of the test structure can change greatly after the first conductive comb tooth portion 101 or the second conductive comb tooth portion 102 is short-circuited, so as to ensure the accuracy of the test.

In an example, the first conductive comb tooth portion 101 includes multiple first conductive comb teeth 1011 arranged in parallel and spaced apart and a first conductive comb body 1012 configured to connect the multiple first conductive comb teeth 1011. The first conductive comb teeth 1011 serve as the comb tooth ends of the first conductive comb tooth portion 101. The second conductive comb tooth portion 102 includes multiple second conductive comb teeth 1021 arranged in parallel and spaced apart and a second conductive comb body 1022 configured to connect the multiple second conductive comb teeth 1021. The second conductive comb teeth 1021 serve as the comb tooth ends of the second conductive comb tooth portion 102. The third conductive comb tooth portion 201 includes multiple third conductive comb teeth 2011 arranged in parallel and spaced apart and a third conductive comb body 2012 configured to connect the multiple third conductive comb teeth 2011. The third conductive comb body 2012 is electrically connected to the first conductive comb body 1012, and the third conductive comb teeth 2011 serve as the comb tooth ends of the third conductive comb tooth portion 201. The fourth conductive comb tooth portion 202 includes multiple fourth conductive comb teeth 2021 arranged in parallel and spaced apart and a fourth conductive comb body 2022 configured to connect the multiple fourth conductive comb teeth 2021. The fourth conductive comb body 2022 is electrically connected to the second conductive comb body 1022, and the fourth conductive comb teeth 2021 serve as the comb tooth ends of the fourth conductive comb tooth portion 202.

Specifically, one end of each first conductive comb tooth 1011 is fixedly connected to one side surface of the first conductive comb body 1012. In this case, when the first conductive comb body 1012 is powered on, the multiple first conductive comb teeth 1011 are connected in series in sequence. One end of each second conductive comb tooth 1021 is fixedly connected to one side surface of the second conductive comb body 1022. In this case, when the second conductive comb body 1022 is powered on, the multiple second conductive comb teeth 1021 are connected in series in sequence. One end of each third conductive comb tooth 2011 is fixedly connected to one side surface of the third conductive comb body 2012. In this case, when the third conductive comb body 2012 is powered on, the multiple third conductive comb teeth 2011 are connected in series in sequence. One end of each fourth conductive comb tooth 2021 is fixedly connected to one side surface of the fourth conductive comb body 2022. In this case, when the fourth conductive comb body 2022 is powered on, the multiple fourth conductive comb teeth 2021 are connected in series in sequence.

The first conductive comb tooth 1011 and the second conductive comb tooth 1021 that are adjacent to each other may serve as a group of metal wires to be detected, and there is a preset first distance d1 between the metal wires to be detected. The first conductive comb body 1012 is configured to be electrically connected to the first conductive comb teeth 1011, and the second conductive comb body 1022 is configured to be electrically connected to the second conductive comb teeth 1021. The third conductive comb tooth 2011 and the fourth conductive comb tooth 2021 that are adjacent to each other may serve as another group of metal wires to be detected, and there is a preset second distance d2 between the metal wires to be detected. The third conductive comb body 2012 is configured to be electrically connected to the third conductive comb teeth 2011, and the fourth conductive comb body 2022 is configured to be electrically connected to the fourth conductive comb teeth 2021. The first conductive comb body 1012 is electrically connected to the fourth conductive comb body 2022, specifically by connecting one end of a metal segment to the first conductive comb body 1012, and connecting the other end of the metal segment to the fourth conductive comb body 2022. The second conductive comb body 1022 and the fourth conductive comb body 2022 serve as a current input end and a current output end of the test structure. If the second conductive comb body 1022 serves as the current input end, the fourth conductive comb body 2022 serves as the current output end; or if the fourth conductive comb body 2022 serves as the current input end, the second conductive comb body 1022 serves as the current output end.

In an example, the quantity of first conductive comb teeth 1011 in each first conductive comb tooth portion 101, the quantity of second conductive comb teeth 1021 in each second conductive comb tooth portion 102, the quantity of the third conductive comb teeth 2011 in each third conductive comb tooth portion 201, and the quantity of the fourth conductive comb teeth 2021 in each fourth conductive comb tooth portion 202 are the same, and the specific value may be set according to actual needs. In FIG. 1, only the quantity of first conductive comb teeth 1011 in each first conductive comb tooth portion 101, the quantity of second conductive comb teeth 1021 in each second conductive comb tooth portion 102, the quantity of the third conductive comb teeth 2011 in each third conductive comb tooth portion 201, and the quantity of the fourth conductive comb teeth 2021 in each fourth conductive comb tooth portion 202 all being four is used as an example. In other examples, the quantity of first conductive comb teeth 1011 in each first conductive comb tooth portion 101, the quantity of second conductive comb teeth 1021 in each second conductive comb tooth portion 102, the quantity of die third conductive comb teeth 2011 in each third conductive comb tooth portion 201, and the quantity of the fourth conductive comb teeth 2021 in each fourth conductive comb tooth portion 202 are not limited to those shown in FIG. 1.

In an example, the first conductive comb teeth 1011, the second conductive comb teeth 1021, the third conductive comb teeth 2011, and the fourth conductive comb teeth 2021 may all be metal wires, and may specifically be copper wires, aluminum wires, nickel wires, gold wires, and the like. The multiple first conductive comb teeth 1011, the multiple second conductive comb teeth 1021, the multiple third conductive comb teeth 2011, and the multiple fourth conductive comb teeth 2021 may be respectively connected in series by metal wire segments of the same material.

It should be noted that a width of the first conductive comb tooth 1011, a width of the second conductive comb tooth 1021, a width of the third conductive comb tooth 2011 and a width of the fourth conductive comb tooth 2021 may be the same or different, which may be set according to actual needs, and is not limited herein. For example, the width of the first conductive comb tooth 1011 is the same as the width of the second conductive comb tooth 1021, the width of the third conductive comb tooth 2011 is the same as the width of the fourth conductive comb tooth 2021, but the width of the first conductive comb tooth 1011 is different from the width of the third conductive comb tooth 2011, so as to detect the minimum distance between metal wires of different widths.

In an example, a length by which the second conductive comb teeth 1021 are inserted into the first conductive comb tooth portion 101 is less than a length of each first conductive comb tooth 1011 and a length of each second conductive comb tooth 1021; and a length by which the fourth conductive comb teeth 2021 are inserted into the third conductive comb tooth portion 201 is less than a length of each third conductive comb tooth 2011 and a length of each fourth conductive comb tooth 2021. Similarly, a length of by which the first conductive comb teeth 1011 are inserted into the second conductive comb tooth portion 102 is less than a length of each first conductive comb tooth 1011 and a length of each second conductive comb tooth 1021; and a length by which the third conductive comb teeth 2011 inserted into the fourth conductive comb tooth portion 202 is less than a length of each third conductive comb tooth 2011 and a length of each fourth conductive comb tooth 2021. By means of the settings above, it can be ensured that the first conductive comb tooth portion 101 and the second conductive comb tooth portion 102 will not be short-circuited when no abnormality occurs.

For the first interdigital structure, one end of each first conductive comb tooth 1011 away from the first conductive comb body 1012 faces the second conductive comb body 1022, but is insulated from the second conductive comb body 1022, and the second conductive comb teeth 1021 are insulated from the first conductive comb body 1012, so that the first conductive comb tooth portion 101 and the second conductive comb tooth portion 102 will not be short-circuited when no abnormality occurs. For the second interdigital structure, one end of each third conductive comb tooth 2011 away from the third conductive comb body 2012 faces the fourth conductive comb body 2022, and is insulated from the fourth conductive comb body 2022, and the fourth conductive comb teeth 2021 are insulated from the third conductive comb body 2012, to avoid a short circuit between the third conductive comb tooth portion 201 and the fourth conductive comb tooth portion 202 when no abnormality occurs.

The insulating arrangement of the first conductive comb teeth 1011 from the second conductive comb body 1022 may include: setting a safe electrical distance between the first conductive comb teeth 1011 and the second conductive comb body 1022, or setting an insulating separator for insulation between the first conductive comb teeth 1011 and the second conductive comb body 1022. The insulating arrangement of the second conductive comb teeth 1021 from the first conductive comb body 1012, the insulating arrangement of the third conductive comb teeth 2011 from the fourth conductive comb body 2022, and the insulating arrangement of the fourth conductive comb teeth 2021 from the third conductive comb body 2012 may all implemented through a safe electrical distance or an insulating separator.

In an example, the length of each first conductive comb tooth 1011 may be the same as the length of each second conductive comb tooth 1021, or may be different from the length of each second conductive comb tooth 1021; and the length of each third conductive comb tooth 2011 may be the same as the length of each fourth conductive comb tooth 2021, or may be different from the length of each fourth conductive comb tooth 2021.

In an example, the length by which the first conductive comb teeth 1011 are inserted into the second conductive comb tooth portion 102 may be ⅔, ⅘, ⅚, or the like of the length of the first conductive comb tooth 1011; the length by which the second conductive comb teeth 1021 are inserted into the first conductive comb tooth portion 101 may be ⅔, ⅘, ⅚, or the like of the length of the second conductive comb tooth 1021; the length by which the third conductive comb teeth 2011 are inserted into the fourth conductive comb tooth portion 202 may be ⅔, ⅘, ⅚, or the like of the length of the third conductive comb tooth 2011; and the length by which the fourth conductive comb teeth 2021 are inserted into the third conductive comb tooth portion 201 may be ⅔, ⅘, ⅚, or the like of the length of the fourth conductive comb tooth 2021. The inserted length needs to meet the safe electrical distance.

In an example, the test structure further includes: a first pad 40, electrically connected to the second conductive comb tooth portion 102; and a second pad 50 electrically connected to the third conductive comb tooth portion 201.

The first pad 40 is connected to an end of the second conductive comb body of the second conductive comb tooth portion 102 away from the voltage divider 30, and the second pad 50 is connected to an end of the third conductive comb body of the third conductive comb tooth portion 201 away from the voltage divider 30.

Specifically, the material for forming the first pad 40 and the material for forming the second pad 50 may be the same as the material for forming the first interdigital structure 10 and the material for forming the second interdigital structure 20. More specifically, the first pad 40 and the second pad 50 may both be metal pads, such as copper pads, aluminum pads, nickel pads, or gold pads.

Specifically, the first pad 40 and the second pad 50 are configured to apply a test voltage. Both the shape of the first pad 40 and the shape of the second pad 50 may be, but is not limited to, square. Certainly, in other examples, the shape of the first pad 40 and the shape of the second pad 50 may be circular or rectangular or the like.

In an example, both the first interdigital structure 10 and the second interdigital structure 20 are located between the first pad 40 and the second pad 50. By disposing the first interdigital structure 10 and the second interdigital structure 20 between the first pad 40 and the second pad 50, a connection lead between the first interdigital structure 10 and the first pad 40 and a connection lead between the second interdigital structure 20 and the second pad 50 can be shortest, so that the test structure is relatively compact, and has a relatively small size.

In an example, both an area of the first pad 40 and an area of the second pad 50 are larger than an occupied area of the first interdigital structure 10 and an occupied area of the second interdigital structure 20. By setting the first pad 40 and the second pad 50 with relatively large areas, it can be ensured that the first pad 40 and the second pad 50 have relatively less resistance, thereby ensuring the sensitivity of the test structure during the testing process.

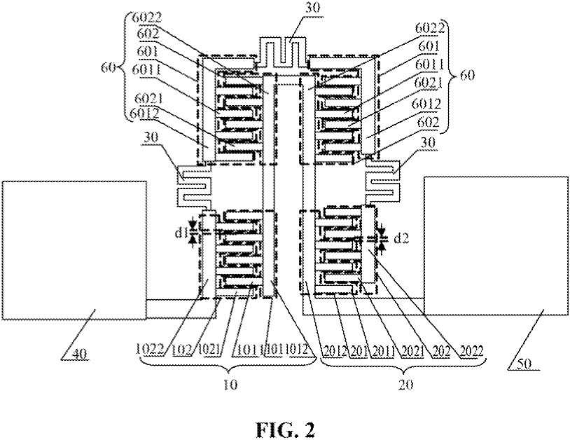

In an example, referring to FIG. 2, the test structure further includes: at least one additional interdigital structure 60, disposed between the first interdigital structure 10 and the second interdigital structure 20, and electrically connected to the first interdigital structure 10 and the second interdigital structure 20. The additional interdigital structure 60 includes a first additional conductive comb tooth portion 601 and a second additional conductive comb tooth portion 602. Comb tooth ends of the second additional conductive comb tooth portion 602 are inserted into the first additional conductive comb tooth portion 601, the comb tooth ends of the second additional conductive comb tooth portion 602 and comb tooth ends of the first additional conductive comb tooth portion 601 are arranged alternately in sequence and spaced apart, and there is an additional distance d3 between the comb tooth end of the second additional conductive comb tooth portion 602 and the comb tooth end of the first additional conductive comb tooth portion 601.

In an example, the quantity of the additional interdigital structures 60 may be set according to actual needs. In this embodiment, there may be multiple additional interdigital structures 60 connected in series in sequence; and the additional distances of the multiple additional interdigital structures 60 are different from each other, and the additional distance of each of the multiple additional interdigital structures 60 is different from each of the first distance d1 and the second distance d2. It should be noted that, an example in which the test structure includes two additional interdigital structures 60 is shown in FIG. 2, but in other examples, the quantity of the additional interdigital structures 60 is not limited to the quantity shown in FIG. 2.

By disposing multiple additional interdigital structures 60, the additional distances of the additional interdigital structures 60 being different from each other, and the additional distance of each additional interdigital structure 60 being different from each of the first distance d1 and the second distance d2, one test structure can test multiple distances at the same time, which can further significantly improve the test efficiency.

Specifically, along the direction from the first interdigital structure 10 via the additional interdigital structures 60 to the second interdigital structure 20, the distances between adjacent conductive comb teeth in the interdigital structures may be sequentially decreased. That is, the first distance d1,the additional distances d3 and the second distance d2 may be sequentially decreased. Certainly, in other examples, along the direction from the first interdigital structure 10 via the additional interdigital structures 60 to the second interdigital structure 20, the distances between adjacent conductive comb teeth in the interdigital structures may be sequentially increased. In other examples, the distances between adjacent conductive comb teeth in the interdigital structures may also vary irregularly.

In an example, two additional interdigital structures 60 are provided for description. The first additional conductive comb tooth portion 601 at an end close to the second conductive comb tooth portion 102 is electrically connected to the second conductive comb tooth portion 102 by a voltage divider 30, the first additional conductive comb tooth portion 601 at another end close to the fourth conductive comb tooth portion 202 is electrically connected to the fourth conductive comb tooth portion 202 by another voltage divider 30, and first additional conductive comb tooth portions 601 of two adjacent additional interdigital structures 60 are connected by a voltage divider 30. The second additional conductive comb tooth portion 602 at an end close to the first conductive comb tooth portion 101 is electrically connected to the first conductive comb tooth portion 101, the second additional conductive comb tooth portion 602 at an end close to the third conductive comb tooth portion 201 is electrically connected to the third conductive comb tooth portion 201, and second additional conductive comb tooth portions 602 of the multiple additional interdigital structures 60 are connected in series in sequence.

In an example, a resistance value of the first conductive comb tooth portion 101, a resistance value of the second conductive comb tooth portion 102, a resistance value of the third conductive comb tooth portion 201, a resistance value of the fourth conductive comb tooth portion 202, a resistance value of the first additional conductive comb tooth portion 601, and a resistance value of the second additional conductive comb tooth portion 602 are all less than a resistance value of the voltage divider 30,

Specifically, the resistance value of the first conductive comb tooth portion 101, the resistance value of the second conductive comb tooth portion 102, the resistance value of the third conductive comb tooth portion 201, the resistance value of the fourth conductive comb tooth portion 202, the resistance value of the first additional conductive comb tooth portion 601, and the resistance value of the second additional conductive comb tooth portion 602 may be all much less than the resistance value of the voltage divider 30. More specifically, the resistance value of the first conductive comb tooth portion 101, the resistance value of the second conductive comb tooth portion 102, the resistance value of the third conductive comb tooth portion 201, the resistance value of the fourth conductive comb tooth portion 202, the resistance value of the first additional conductive comb tooth portion 601, and the resistance value of the second additional conductive comb tooth portion 602 may be, but is not limited to, less than 10% of the resistance value of the voltage divider 30, such as 10%, 5%, or 1% of the resistance value of the voltage divider 30.

In an example, as shown in FIG. 2, the first additional conductive comb tooth portion 601 includes multiple first additional conductive comb teeth 6011 arranged in parallel and spaced apart and a first additional conductive comb body 6012 configured to connect the multiple first additional conductive comb teeth 6011, the first additional conductive comb teeth 6011 serving as the comb tooth ends of the first additional conductive comb tooth portion 601.The second additional conductive comb tooth portion 602 includes multiple second additional conductive comb teeth 6021 arranged in parallel and spaced apart and a second additional conductive comb body 6022 configured to connect the multiple second additional conductive comb teeth 6021, the second additional conductive comb teeth 6021 serving as the comb tooth ends of the second additional conductive comb tooth portion 602.

The multiple additional interdigital structures 60 are connected in series in sequence, and the multiple additional interdigital structures 60 are connected to each other specifically by the first additional conductive comb body 6012 of each additional interdigital structure 60. The first additional conductive comb body 6012 located at the head of the series connection is further connected to the first conductive comb body 1012, and the first additional conductive comb body 6012 located at the tail of the series connection is further connected to the fourth conductive comb body 2022. A voltage divider 30 is further electrically connected between two adjacent additional interdigital structures 60, a same voltage divider 30 is electrically connected between the additional interdigital structure 60 and the first interdigital structure 10, and a same voltage divider 30 is electrically connected between the additional interdigital structure 60 and the second interdigital structure 20. The second additional conductive comb body 6022 of the additional interdigital structure 60 is connected to the voltage divider 30.

In an example, the quantity of the first additional conductive comb teeth 6011 in each first additional conductive comb tooth portion 601 is the same as the quantity of the second additional conductive comb teeth 6021 in the second additional conductive comb tooth portion 602, and the specific value may be set according to actual needs. In FIG. 2, only the quantity of the first additional conductive comb teeth 6011 in each first additional conductive comb tooth portion 601 and the quantity of the second additional conductive comb teeth 6021 in each second additional conductive comb tooth portion 602 being both four is taken as an example. In other examples, the quantity of the first additional conductive comb teeth 6011 in each first additional conductive comb tooth portion 601 and the quantity of the second additional conductive comb teeth 6021 in each second additional conductive comb tooth portion 602 are not limited to the quantity shown in FIG. 2.

In an example, the first additional conductive comb teeth 6011 and the second conductive comb teeth 6021 may both be metal wires, and may specifically be copper wires, aluminum wires, nickel wires, gold wires, and the like. The multiple first additional conductive comb teeth 6011 and the multiple second conductive comb teeth 6021 may be connected in series by other metal wires respectively.

It should be noted that a width of each first additional conductive comb tooth 6011 and a width of each second conductive comb tooth 6021 may be the same or different, and are set according to actual needs, which are not limited herein.

In an example, a length by which the second additional conductive comb teeth 6021 are inserted into the first additional conductive comb tooth portion 601 is less than a length of each first additional conductive comb tooth 6011 and a length of each second additional conductive comb tooth 6021. Similarly, a length by which the first additional conductive comb teeth 6011 are inserted into the second additional conductive comb tooth portion 602 is less than a length of each first additional conductive comb tooth 6011 and a length of each second additional conductive comb tooth 6021. By means of the settings above, it can be ensured that the first additional conductive comb tooth portion 601 and the second additional conductive comb tooth portion 602 will not be short-circuited when no abnormality occurs.

Specifically, one end of each first additional conductive comb tooth 6011 away from the first additional conductive comb body 6012 faces the second additional conductive comb body 6022, but is insulated from the second additional conductive comb body 6022, and the second additional conductive comb teeth 6021 are insulated from the first additional conductive comb body 6012, so that the first additional conductive comb tooth portion 601 and the second additional conductive comb tooth portion 602 will not be short-circuited when no abnormality occurs.

More specifically, the insulating arrangement of the first additional conductive comb teeth 6011 from the second additional conductive comb body 6022 may include: setting a safe electrical distance between the first additional conductive comb teeth 6011 and the second additional conductive comb body 6022, or setting an insulating separator for insulation between the first additional conductive comb teeth 6011 and the second additional conductive comb body 6022. The insulating arrangement of the second additional conductive comb teeth 6021 from the first additional conductive comb body 6012 may also be implemented through a safe electrical distance or an insulating separator.

In an example, a length of each first additional conductive comb tooth 6011 may be the same as a length of the second additional conductive comb tooth 6021, or may be different from a length of each second additional conductive comb tooth 6021.

In an example, a length by which the first additional conductive comb teeth 6011 are inserted into the additional conductive comb tooth portion 602 may be ⅔, ⅘, ⅚, or the like of the length of the first additional conductive comb tooth 6011; and a length by which the second additional conductive comb teeth 6021 are inserted into the first additional conductive comb tooth portion 601 may be ⅔, ⅘, ⅚, or the like of the length of the second additional conductive comb tooth 6021.

It should be noted that, in the foregoing embodiments, the resistance value of the first conductive comb teeth 1011, the resistance value of the second conductive comb teeth 1021, the resistance value of the third conductive comb teeth 2011, the resistance value of the fourth conductive comb teeth 2021, the resistance value of the voltage divider 30, the resistance value of the first additional conductive comb teeth 6011, and the resistance value of the second additional conductive comb teeth 6021 are all known, and a resistance value of a metal wire for connecting multiple first conductive comb teeth 1011 in the same first conductive comb tooth portion 101 in series in sequence, a resistance value of a metal wire connecting multiple second conductive comb teeth 1021 in the same second conductive comb tooth portion 102 in series in sequence, a resistance value of a metal wire connecting multiple third conductive comb teeth 2011 in the same third conductive comb tooth portion 201 in series in sequence, a resistance value of a metal wire connecting multiple fourth conductive comb teeth 2021 in the same fourth conductive comb tooth portion 202 in series in sequence, a resistance value of a metal wire connecting multiple first additional conductive comb teeth 6011 in the same first additional conductive comb tooth portion 601 in series in sequence, and a resistance value of a metal wire connecting multiple second additional conductive comb teeth 6021 in the same second additional conductive comb tooth portion 602 in series in sequence may be all negligible.

The test structure in FIG. 2 is taken as an example. The test principle of the test structure is as follows. Test voltages are applied to the first pad 40 and the second pad 50, where there is a voltage difference between the test voltage applied to the first pad 40 and the test voltage applied to the second pad 50, for example, a high voltage is applied to the first pad 40, and a low voltage is applied to the second pad 50; and a current detection apparatus is used to detect a resulting current. If a short circuit occurs between the first conductive comb teeth 1011 and the second conductive comb teeth 1021 in the first interdigital structure 10 due to an excessively short distance, and the current path is from the first pad 40, via the second conductive comb body 1022, the first conductive comb teeth 1011, the second conductive comb teeth 1021, the second conductive comb body 1022, the second conductive comb body 1022 of the additional interdigital structure 60, and the fourth conductive comb body 2022, to the second pad 50, the current value obtained by the current detection apparatus is equal to the difference between the voltages applied to the first pad 40 and the second pad 50 divided by a sum of the resistance value of the first conductive comb teeth 1011 and the resistance value of the second conductive comb teeth 1021 in the first interdigital structure 10. If a short circuit occurs between the first additional conductive comb teeth 6011 and the second additional conductive comb teeth 6021 in an additional interdigital structure 60 adjacent to the first interdigital structure 10 due to an excessively short distance, the current value obtained by the current detection apparatus is equal to the difference between the voltages applied to the first pad 40 and the second pad 50 divided by a sum of the resistance value of one voltage divider 30, the resistance value of the first additional conductive comb teeth 6011, and the resistance value of the second additional conductive comb teeth 6021. If a short circuit occurs between the first additional conductive comb teeth 6011 and the second additional conductive comb teeth 6021 in an additional interdigital structure 60 adjacent to the second interdigital structure 20, the current value obtained by the current detection apparatus is equal to the difference between the voltages applied to the first pad 40 and the second pad 50 divided by a sum of resistance values of two voltage dividers 30, the resistance value of the first additional conductive comb teeth 6011, and the resistance value of the second additional conductive comb teeth 6021. If a short circuit occurs between the third conductive comb teeth 2011 and the fourth conductive comb teeth 2021 in the second interdigital structure 20, the current value obtained by the current detection apparatus is equal to the difference between the voltages applied to the first pad 40 and the second pad 50 divided by a sum of resistance values of three voltage dividers 30, the resistance value of the third conductive comb teeth 2011, and the resistance value of the fourth conductive comb teeth 2021. In this way, the position of the short circuit can be determined based on the detected current value. If the interdigital structures have different distances, the shortest distance between metal wires is determined according to the short circuit position.

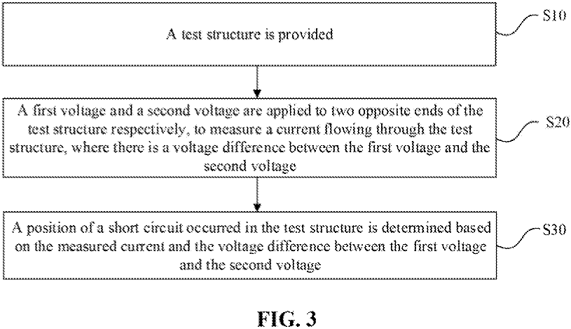

Referring to FIG. 3 in conjunction with FIGS. 1 and 2, an embodiment of the disclosure further provides a test method, including the following operations.

S10: the test structure according to any one of the foregoing embodiments is provided.

S20: a first voltage and a second voltage are applied to two opposite ends of the test structure respectively, to measure a current flowing through the test structure, where there is a voltage difference between the first voltage and the second voltage.

S30: a position of a short circuit occurred in the test structure is determined based on the measured current and the voltage difference between the first voltage and the second voltage.

The test method in the embodiment of the disclosure can test two or more distances based on the same test structure at the same time, which can significantly improve the test efficiency, and determine a distance in an interdigital structure at which the short circuit position is located as the shortest distance for arrangement of the metal wire. In addition, the test structure used in the test method in the embodiment of the disclosure is relatively compact, and has a relatively small size.

Specifically, for the specific structure of the test structure, reference may be made to FIG. 1 and FIG. 2 and the specific descriptions of the test structure in the foregoing embodiments, which will not be described herein again.

In an example, in S20, a first voltage may be applied to the first pad 40, and a second voltage may be applied to the second pad 50. The first voltage may be a high voltage, and the second voltage may be a low voltage. The high voltage and the low voltage herein are only a relative concept, that is, it means that the first voltage is higher than the second voltage.

In an example, in S30, by taking FIG. 2 as an example, the specific determination method is as follows. If a short circuit occurs between the first conductive comb teeth 1011 and the second conductive comb teeth 1021 in the first interdigital structure 10, a current value obtained by the current detection apparatus is equal to the difference between the voltages applied to the first pad 40 and the second pad 50 divided by a sum of a resistance value of the first conductive comb teeth 1011 and a resistance value of the second conductive comb teeth 1021 in the first interdigital structure 10. If a short circuit occurs between the first additional conductive comb teeth 6011 and the second additional conductive comb teeth 6021 in an additional interdigital structure 60 adjacent to the first interdigital structure 10, the current value obtained by the current detection apparatus is equal to the difference between the voltages applied to the first pad 40 and the second pad 50 divided by a sum of a resistance value of one voltage divider 30, a resistance value of the first additional conductive comb teeth 6011, and a resistance value of the second additional conductive comb teeth 6021. If a short circuit occurs between the first additional conductive comb teeth 6011 and the second additional conductive comb teeth 6021 in an additional interdigital structure 60 adjacent to the second interdigital structure 20, the current value obtained by the current detection apparatus is equal to the difference between the voltages applied to the first pad 40 and the second pad 50 divided by a sum of resistance values of two voltage dividers 30, a resistance value of the first additional conductive comb teeth 6011, and a resistance value of the second additional conductive comb teeth 6021. If a short circuit occurs between the third conductive comb teeth 2011 and the fourth conductive comb teeth 2021 in the second interdigital structure 20, the current value obtained by the current detection apparatus is equal to the difference between the voltages applied to the first pad 40 and the second pad 50 divided by a sum of resistance values of three voltage dividers 30, a resistance value of the third conductive comb teeth 2011, and a resistance value of the fourth conductive comb teeth 2021. An interdigital structure in which the short circuit occurs is determined by a magnitude of the current value, and a distance of the short-circuited interdigital structure is determined as the shortest distance for arranging the metal wires, where the metal wires are intended for configuring conductive comb teeth of the short-circuited interdigital structure and are arranged in other areas of the chip to connect different semiconductor devices.

It should be understood that, unless explicitly specified herein, there is no strict order in execution of the steps and the steps may be performed in other orders. Moreover, at least some of the steps may include multiple sub-steps or multiple stages. The sub-steps or stages are not necessarily performed at the same moment, but may be performed at different moments. The sub-steps or stages are not necessarily performed sequentially, but may be performed in turn or alternately with another step or at least some of sub-steps or stages of the another step.

The embodiments in this specification are all described in a progressive manner. Description of each embodiment focuses on differences from other embodiments, and reference may be made to each other for the same or similar pans among the embodiments.

The technical features in the foregoing embodiments may be randomly combined. For concise description, not all possible combinations of the technical features in the embodiments are described. However, provided that combinations of the technical features do not conflict with each other, the combinations of the technical features should be considered as falling within the scope recorded in this specification.

The foregoing embodiments only represent several implementations of the disclosure, and the descriptions thereof are relatively detailed, but should not be construed as limiting the patent scope of the application. It should be noted that, for a person of ordinary skill in the art, several modifications and improvements may still be made without departing from the concept of the disclosure, which all fall within the protection scope of the disclosure. Therefore, the protection scope of the disclosure should be determined by the appended claims.

1. A test structure, comprising:
a first interdigital structure, comprising a first conductive comb tooth portion and a second conductive comb tooth portion, wherein comb tooth ends of the second conductive comb tooth portion are inserted into the first conductive comb tooth portion, the comb tooth ends of the second conductive comb tooth portion and comb tooth ends of the first conductive comb tooth portion are arranged alternately in sequence and spaced apart, and there is a first distance between the comb tooth end of the second conductive comb tooth portion and the comb tooth end of the first conductive comb tooth portion; and
a second interdigital structure, comprising a third conductive comb tooth portion and a fourth conductive comb tooth portion, wherein comb tooth ends of the fourth conductive comb tooth portion are inserted into the third conductive comb tooth portion, the comb tooth ends of the fourth conductive comb tooth portion and comb tooth ends of the third conductive comb tooth portion are arranged alternately in sequence and spaced apart, and there is a second distance between the comb tooth end of the fourth conductive comb tooth portion and the comb tooth end of the third conductive comb tooth portion, the second distance being not equal to the first distance; and wherein the first conductive comb tooth portion is electrically connected to the third conductive comb tooth portion, and the second conductive comb tooth portion is electrically connected to the fourth conductive comb tooth portion.

2. The test structure according to claim 1, further comprising a voltage divider, electrically connecting the second conductive comb tooth portion to the fourth conductive comb tooth portion.

3. The test structure according to claim 2, wherein a resistance value of the first conductive comb tooth portion, a resistance value of the second conductive comb tooth portion, a resistance value of the third conductive comb tooth portion, and a resistance value of the fourth conductive comb tooth portion are all less than a resistance value of the voltage divider.

4. The test structure according to claim 1, wherein the first conductive comb tooth portion comprises a plurality of first conductive comb teeth arranged in parallel and spaced apart and a first conductive comb body configured to connect the plurality of first conductive comb teeth, the first conductive comb teeth serving as the comb tooth ends of the first conductive comb tooth portion; the second conductive comb tooth portion comprises a plurality of second conductive comb teeth arranged in parallel and spaced apart and a second conductive comb body configured to connect the plurality of second conductive comb teeth, the second conductive comb teeth serving as the comb tooth ends of the second conductive comb tooth portion; and
the third conductive comb tooth portion comprises a plurality of third conductive comb teeth arranged in parallel and spaced apart and a third conductive comb body configured to connect the plurality of third conductive comb teeth, the third conductive comb body being connected to the first conductive comb body, and the third conductive comb teeth serving as the comb tooth ends of the third conductive comb tooth portion; and the fourth conductive comb tooth portion comprises a plurality of fourth conductive comb teeth arranged in parallel and spaced apart and a fourth conductive comb body configured to connect the plurality of fourth conductive comb teeth, the fourth conductive comb body being electrically connected to the second conductive comb body, and the fourth conductive comb teeth serving as the comb tooth ends of the fourth conductive comb tooth portion.

5. The test structure according to claim 4, wherein a length by which the second conductive comb teeth are inserted into the first conductive comb tooth portion is less than a length of each first conductive comb tooth and a length of each second conductive comb tooth; and a length by which the fourth conductive comb teeth are inserted into the third conductive comb tooth portion is less than a length of each third conductive comb tooth and a length of each fourth conductive comb tooth.

6. The test structure according to claim 1, further comprising:
a first pad, electrically connected to the second conductive comb tooth portion; and
a second pad, electrically connected to the third conductive comb tooth portion.

7. The test structure according to claim 6, wherein both the first interdigital structure and the second interdigital structure are located between the first pad and the second pad.

8. The test structure according to claim 7, wherein both an area of the first pad and an area of the second pad are larger than an area of the first interdigital structure and an area of the second interdigital structure.

9. The test structure according to claim 1, further comprising:
at least one additional interdigital structure, disposed between the first interdigital structure and the second interdigital structure, and electrically connected to the first interdigital structure and the second interdigital structure, wherein the additional interdigital structure comprises a first additional conductive comb tooth portion and a second additional conductive comb tooth portion, wherein comb tooth ends of the second additional conductive comb tooth portion are inserted into the first additional conductive comb tooth portion, the comb tooth ends of the second additional conductive comb tooth portion and comb tooth ends of the first additional conductive comb tooth portion are arranged alternately in sequence and spaced apart, and there is an additional distance between the comb tooth end of the second additional conductive comb tooth portion and the comb tooth end of the first additional conductive comb tooth portion.

10. The test structure according to claim 9, wherein there are a plurality of additional interdigital structures connected in series in sequence; and additional distances of the plurality of additional interdigital structures are different from each other, and the additional distance of each of the additional interdigital structures is different from each of the first distance and the second distance.

11. The test structure according to claim 10, wherein the first additional conductive comb tooth portion at an end close to the second conductive comb tooth portion is electrically connected to the second conductive comb tooth portion by a voltage divider, the first additional conductive comb tooth portion at another end close to the fourth conductive comb tooth portion is electrically connected to the fourth conductive comb tooth portion by another voltage divider, and first additional conductive comb tooth portions of two adjacent additional interdigital structures are connected by a voltage divider; and wherein the second additional conductive comb tooth portion at an end close to the first conductive comb tooth portion is electrically connected to the first conductive comb tooth portion, the second additional conductive comb tooth portion at an end close to the third conductive comb tooth portion is electrically connected to the third conductive comb tooth portion, and second additional conductive comb tooth portions of the plurality of additional interdigital structures are connected in series in sequence.

12. The test structure according to claim 10, wherein a resistance value of the first conductive comb tooth portion, a resistance value of the second conductive comb tooth portion, a resistance value of the third conductive comb tooth portion, a resistance value of the fourth conductive comb tooth portion, a resistance value of the first additional conductive comb tooth portion, and a resistance value of the second additional conductive comb tooth portion are all less than a resistance value of the additional voltage divider.

13. The test structure according to claim 9, wherein the first additional conductive comb tooth portion comprises a plurality of first additional conductive comb teeth arranged in parallel and spaced apart and a first additional conductive comb body configured to connect the plurality of first additional conductive comb teeth, the first additional conductive comb teeth serving as the comb tooth ends of the first additional conductive comb tooth portion; and
the second additional conductive comb tooth portion comprises a plurality of second additional conductive comb teeth arranged in parallel and spaced apart and a second additional conductive comb body configured to connect the plurality of second additional conductive comb teeth, the second additional conductive comb teeth serving as the comb tooth ends of the second additional conductive comb tooth portion.

14. The test structure according to claim 13, wherein a length by which the second additional conductive comb teeth are inserted into the first additional conductive comb tooth portion is less than a length of each first additional conductive comb tooth and a length of each second additional conductive comb tooth.

15. A test method, comprising:
providing a test structure, wherein the test structure comprises:
a first interdigital structure, comprising a first conductive comb tooth portion and a second conductive comb tooth portion, wherein comb tooth ends of the second conductive comb tooth portion are inserted into the first conductive comb tooth portion, the comb tooth ends of the second conductive comb tooth portion and comb tooth ends of the first conductive comb tooth portion are arranged alternately in sequence and spaced apart, and there is a first distance between the comb tooth end of the second conductive comb tooth portion and the comb tooth end of the first conductive comb tooth portion; and
a second interdigital structure, comprising a third conductive comb tooth portion and a fourth conductive comb tooth portion, wherein comb tooth ends of the fourth conductive comb tooth portion are inserted into the third conductive comb tooth portion, the comb tooth ends of the fourth conductive comb tooth portion and comb tooth ends of the third conductive comb tooth portion are arranged alternately in sequence and spaced apart, and there is a second distance between the comb tooth end of the fourth conductive comb tooth portion and the comb tooth end of the third conductive comb tooth portion, the second distance being not equal to the first distance; and wherein the first conductive comb tooth portion is electrically connected to the third conductive comb tooth portion, and the second conductive comb tooth portion is electrically connected to the fourth conductive comb tooth portion;
applying a first voltage and a second voltage to two opposite ends of the test structure respectively, to measure a current flowing through the test structure, where there is a voltage difference between the first voltage and the second voltage; and
determining a position of a short circuit occurred in the test structure based on the measured current and the voltage difference between the first voltage and the second voltage.
